(19) United States
(12) Patent Application Publication
(10) Pub. No.: US 2014/0363021 A1
(43) Pub. Date: Dec. 11, 2014

(54) Collar/headset microphone cable control device

(71) Applicant: Sheng-Jie Wang, Kaohsiung (TW)

(72) Inventor: Sheng-Jie Wang, Kaohsiung (TW)

(21) Appl. No.: 14/468,346

(22) Filed: Aug. 26, 2014

(51) Int. Cl. H04R 1/08; H03G 3/02; H04R 1/02; H04R 3/00

(52) U.S. Cl. CPC H04R 1/08; H04R 3/00; H03G 3/02; H04R 1/02
USPC 381/98

(57) ABSTRACT

A collar/headset microphone cable control device is provided with a sound receiving part and a radio frequency emitting part. The sound receiving part includes a microphone sound receiving end for picking up the sound signal inputs, and a microphone cable control end electrically connected to the microphone sound receiving end for controlling the sound signal transmission state. The radio frequency emitting part includes a substrate, a microphone signal receiving element, a built-in sound receiving end, an external sound signal receiving element, a signal emitting element, buttons, indicator lights, a display element and a bus element that all are provided on the substrate and are electrically interconnected. The microphone signal receiving element picks up sound signals from the microphone cable control end. The built-in sound receiving end receives additional sound signals. A user can easily control the sound volume level and muteness on the microphone sound source cable.

### BACKGROUND OF THE INVENTION

1. Field of the Invention

The invention relates to a cable control device and more particularly to a collar/headset microphone cable control device that allows to adjust the volume level and to select mute directly on the microphone sound source cable.

2. Description of Related Art

Microphones are often used in lecture, teaching, entertainment activities and television programs. For the smooth and convenience of use and mobility, mini collar/headset microphones are mostly chosen.

However, when the user needs to control the volume level and muteness, the user can not control the volume level and muteness directly on the microphone sound source cable. Instead, the user has to use the sound broadcast device carried by the user, or needs to walk to sound broadcast control equipment at another position for adjustment. It is extremely inconvenient to use.

Thus, the need for improvement still exists.

### SUMMARY OF THE INVENTION

It is therefore one object of the invention to provide a provide a cable control device that allows to adjust the volume level and to select mute of the collar/headset microphone using the cable control part on the microphone sound source cable directly.

In order to achieve the above objective, the collar/headset microphone cable control device of the invention mainly comprises a sound receiving part and a radio frequency emitting part, wherein the sound receiving part includes a microphone sound receiving end, for picking up the sound signal inputs, and a microphone cable control end which is electrically connected to the microphone sound receiving end and controls the sound signal transmission state; the radio frequency emitting part includes a substrate and a microphone signal receiving element, a built-in sound receiving end, an external sound signal receiving element, a signal emitting element, buttons, indicator lights, a display element and a bus element that all are installed on the substrate and are electrically connected to one another, whereas the microphone signal receiving element can pick up sound signals from the microphone cable control end and the built-in sound receiving end can receive additional sound signals.

The user needs to turn on the main receiving host and the signal amplifier first and the main receiving host automatically scans the selected channels. When the user wants to use the cable control device, press the button to start the radio frequency emitting part. When the power indictor light of the radio frequency emitting part is on, it indicates that the radio frequency emitting part has started and is in normal operation. The user can press the frequency verification button to initiate the wireless connection between the signal emitting element and the main receiving host. The main receiving host is also electrically connected to the signal amplifier; the signal amplifier is electrically connected to the sound broadcast device; the display element displays the operational condition of the cable control device. The user can use the buckle part on the radio frequency emitting part to clip and attach the device to the garment for the convenience of movement.

Next, the user can apply the buttons of the radio frequency emitting part to control the signal strength, sound volume scale and muteness, as well as can directly speak to the built-in sound receiving end of the radio frequency emitting part, so that the sound broadcast device will receive sound signals and generate sound. In addition, by connecting to the sound receiving part, such as a collar microphone, the user can speak directly to the microphone sound receiving end and control the level of volume and muteness from the microphone cable control end. The sound broadcast device also can receive sound signals and generate sound.

If a headset-styled microphone is used instead, in additional to the microphone cable control end of the sound source cable of the sound receiving part, the microphone sound receiving end can be also equipped with a microphone cable control end. The cable control ends of both locations can control the level of sound volume and muteness; when the user speaks to the microphone sound receiving end, the sound broadcast device can also receive sound signals and generate sound. After the radio frequency emitting part is used for a long period of time, the power of the radio frequency emitting part is consumed completely and needs power charging. A charger can be used to connect to the bus element for charging power to the radio frequency emitting part.

Further more, the radio frequency emitting part can be connected to a sound signal storage device and transmit the sound signals from the sound signal storage device to the sound broadcast device through the signal emitting element for broadcast. Eventually, the old styled microphone can be connected to a switch part. Once being connected to the switch part, the user can use the switch cable control end of the switch part to control the level of sound volume and muteness directly.

The above and other objects, features and advantages of the invention will become apparent from the following detailed description taken with the accompanying drawings.

### BRIEF DESCRIPTION OF THE DRAWINGS

FIG. 1A is a top view of the radio frequency emitting part of a cable control device of the invention;

FIG. 1B is a schematic diagram of the structure of the invention;

FIG. 2 is another schematic diagram of the structure of the invention;

FIG. 3 is a schematic diagram of an embodiment of the invention;

FIG. 4 is another schematic diagram of the embodiment of the invention;

FIG. 5 is yet another schematic diagram of the embodiment of the invention; and

FIG. 6 is a further schematic diagram of the embodiment of the invention.

### DETAILED DESCRIPTION OF THE INVENTION

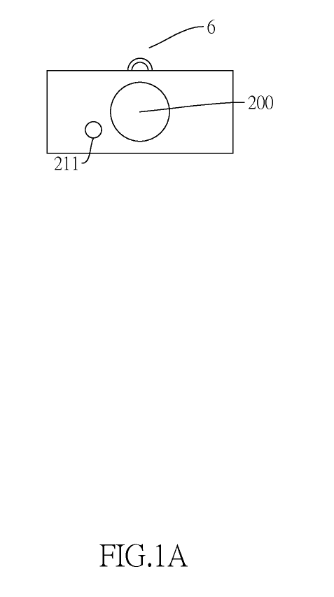

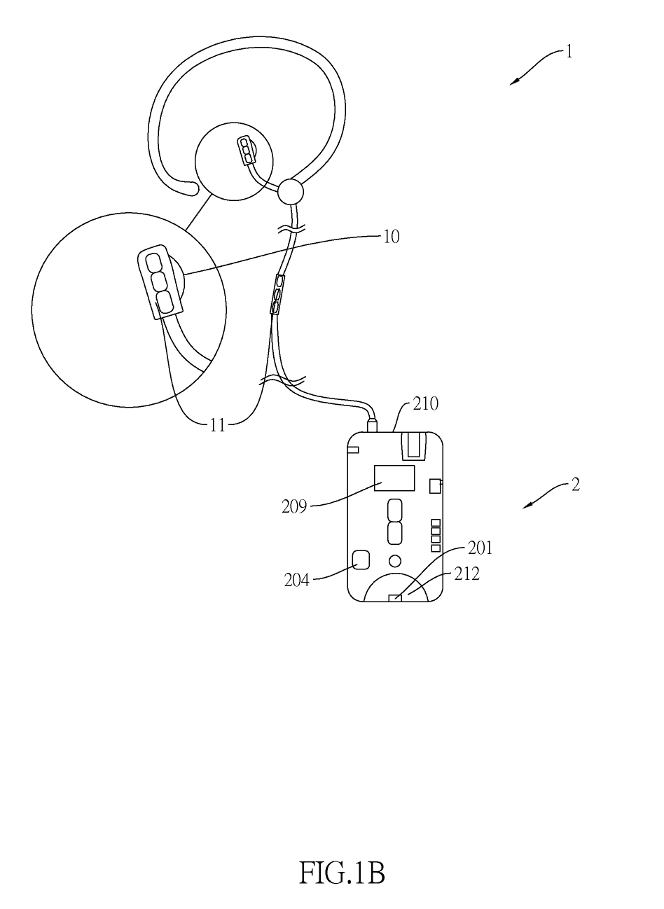

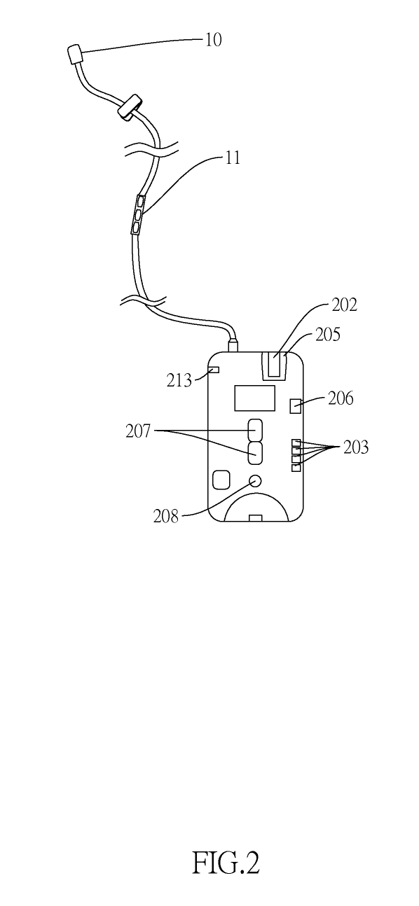

Referring to FIGS. 1A, 1B, and 2, a collar/headset microphone cable control device in accordance with the invention comprises the following components as discussed in detail below.

A sound receiving part (1) and a radio frequency emitting part (2) are provided wherein the sound receiving part (1) includes a microphone sound receiving end (10), for picking up the sound signal inputs, and a microphone cable control end (11) which is electrically connected to the microphone sound receiving end (10) and controls the sound signal transmission state; and the radio frequency emitting part (2) includes a substrate (210) and a microphone signal receiving element (211), a built-in sound receiving end (200), an external sound signal receiving element (213), a signal emitting element (212), a frequency verification button (204), a power button (205), a signal strength switch button (206), a volume button (207), a mute button (208), a power indicator light (202), a power charging indicator light (203), a display element (209), and a bus element (201) that all are installed on the substrate (210) and are electrically connected to one another, whereas the microphone signal receiving element (211) can pick up sound signals from the microphone cable control end (11); the built-in sound receiving end (200) can receive additional sound signals; and the radio frequency emitting part (2) has a buckle part (6).

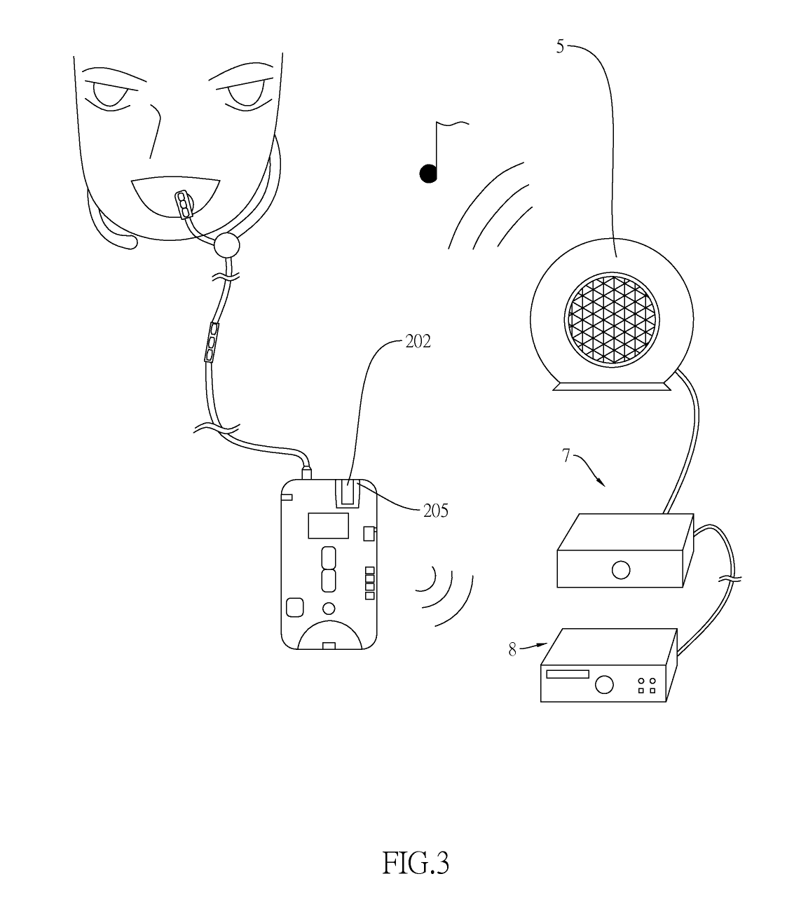

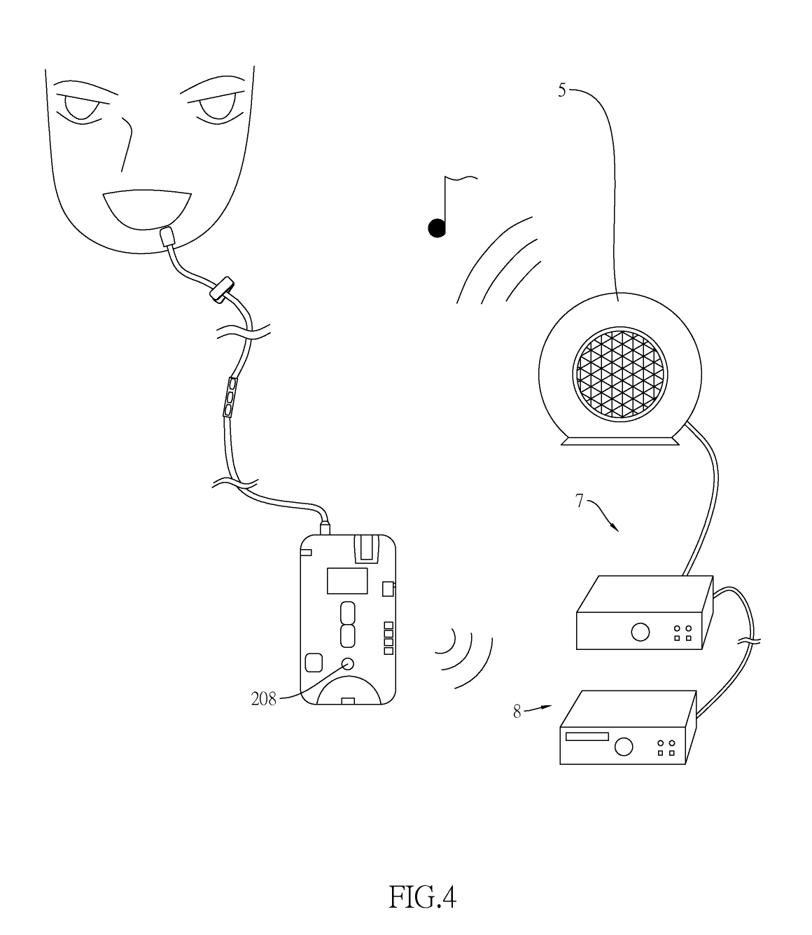

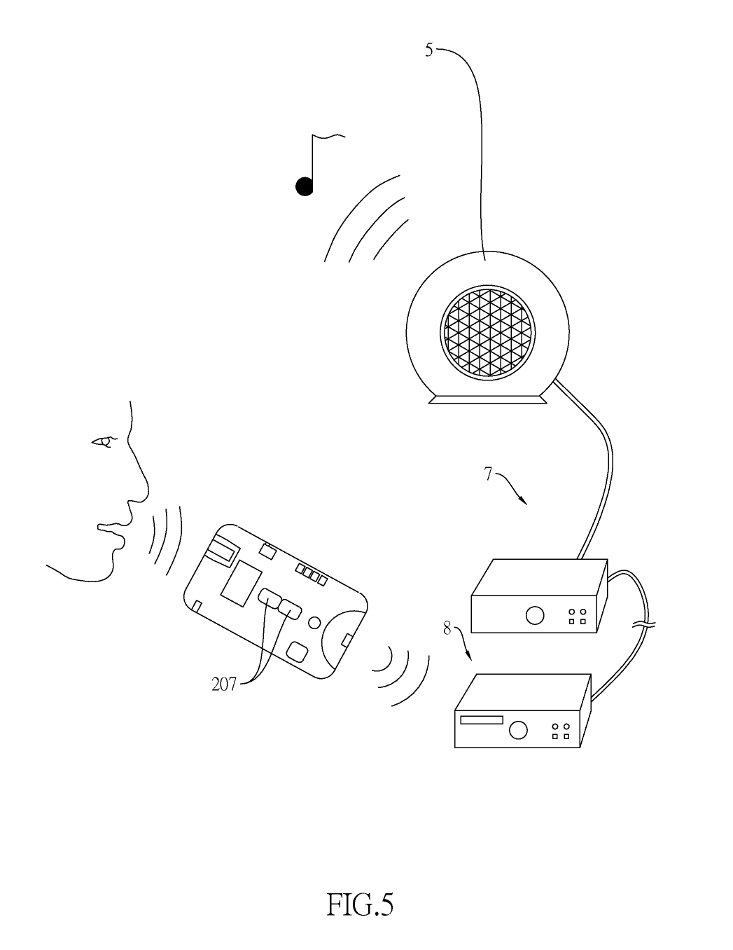

Referring to FIGS. 3, 4, and 5 in conjunction with FIGS. 1A, 1B, and 2, according to the diagrams, the cable control device can be implemented in the collar microphones or headset microphones. The user needs to turn on the main receiving host (8) and the signal amplifier (7) first and to set the level of sound volume. The main receiving host (8) will automatically scan the channel that has least noise interference to select a fixed channel. Next, the user presses the power button (205) first. When the power indictor light (202) is on, it indicates that the radio frequency emitting part (2) has started and is in normal operation. Press the frequency verification button (204) to initiate the signal emitting element (212) to send signals for inquiring the channel selected by the main receiving host (8). When the main receiving host (8) returns signals to the signal emitting element (212), the signal emitting element (212) will establish the wireless connection with the main receiving host (8). When the channel in use encounters strong interference, the main receiving host (8) will automatically switch to a new channel; the main receiving host (8) will notify the signal emitting element (212); and the signal emitting element (212) will automatically adjust to that specific channel accordingly. The user can use the buckle part (6) on the radio frequency emitting part (2) to clip and attach the device to the garment for the convenience of movement.

When in use, the user speaks to the microphone sound receiving end (10) or the built-in sound receiving end (200). After the user spoke to the microphone sound receiving end (10), the microphone sound receiving end (10) transmits the sound signals to the microphone signal receiving element (211) after receiving the sound signals and, through the use of the microphone cable control end (11), the level of sound volume and muteness can be controlled directly. When the microphone cable control end (11) is implemented with the headset microphone, it can be installed on the microphone sound receiving end (1) or the microphone sound source cable. Consequently, the microphone signal receiving element (211) transmits analog sound signals to the signal emitting element (212) for converting into digital sound signals and then transmitting to the main receiving host (8) afterward. The main receiving host (8), which is electrically connected to the signal amplifier (7), converts the signals into analog sound signals and transmits the analog sound signals to the signal amplifier (7). The signal amplifier (7), electrically connected to the sound broadcast device (5), forwards the sound signals to the sound broadcast device (5) to play out the sound signal content.

In addition, the user can use the volume button (207) and the mute button (208) of the radio frequency emitting part (2) directly to control the level of sound volume and the mute condition. If the sound signal content played by the sound broadcast device (5) is intermittent, press the signal strength switch button (206) to increase the signal strength level of the signal emitting element (212) and the sound signal content will become more clear and smooth.

When the user finishes the speech and relocates from the first location to the second location, the user can restart the device; press the frequency verification button (204) to connect to main receiving host (8) via the wireless connection quickly; and proceed the next speech. The display element (209) will show the signal state, sound volume scale, and mute state during the user's operation for the user to judge the usage condition conveniently.

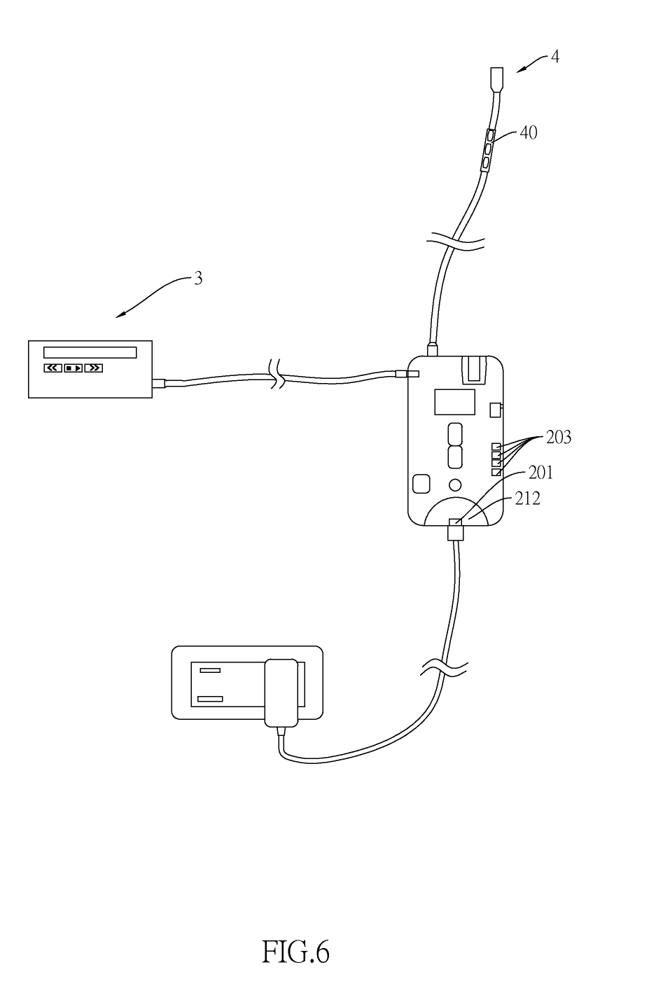

Referring to FIG. 6 in conjunction with FIGS. 1A, 1B, 2, and 3, according to these diagrams, the radio frequency emitting part (2) also can be connected to a sound signal storage device (3) to transmit the sound signals stored in the sound signal storage device (3) to the external sound signal receiving element (213) or the bus element (201). The sound signals then are transmitted by the signal emitting element (212) to the main receiving host (8), sent to the signal amplifier (7), and forwarded to the sound broadcast device (5) to be played out. Furthermore, the old styled microphone and the sound signal storage device (3) can be connected to a switch part (4) for controlling the level of sound volume and muteness through the switch cable control end (40) of the switch part (4). When the power of the radio frequency emitting part (2) is insufficient or consumed completely, the power indicator light (202) will flash and change its color to remind the user. The user can connect a charger to the bus element (201) and the power charging indicator light (203) will display the scale of charged electricity to the user.

While the invention has been described in terms of preferred embodiments, those skilled in the art will recognize that the invention can be practiced with modifications within the spirit and scope of the appended claims.

What is claimed is:

1. A collar/headset microphone cable control device, comprising a sound receiving part and a radio frequency emitting part, wherein
the sound receiving part includes a microphone sound receiving end for picking up the sound signal inputs, and a microphone cable control end which is electrically connected to the microphone sound receiving end and controls the sound signal transmission state; and
the radio frequency emitting part includes a substrate, a microphone signal receiving element, a built-in sound receiving end, an external sound signal receiving element, a signal emitting element, buttons, indicator lights, a display element, and a bus element that all are installed on the substrate and are electrically connected to one another wherein the microphone signal receiving element can pick up sound signals from the microphone cable control end and the built-in sound receiving end can receive additional sound signals.

2. The collar/headset microphone cable control device as claimed in claim 1, wherein the signal emitting element can be connected to the main receiving host via the wireless connection; the main receiving host is electrically connected to the signal amplifier; and the signal amplifier is electrically connected to the sound broadcast device.

3. The collar/headset microphone cable control device as claimed in claim 1, wherein the external sound signal receiving element and the bus element are electrically connected to a sound signal storage device.

4. The collar/headset microphone cable control device as claimed in claim 1, wherein the radio frequency emitting part has a buckle part.

5. The collar/headset microphone cable control device as claimed in claim 1, wherein the microphone signal receiving element and the bus element are electrically connected to a switch part and the switch part has a switch cable control end.

6. The collar/headset microphone cable control device as claimed in claim 1, wherein the buttons include a power button, a signal strength switch button, a frequency verification button, a volume button, and a mute button whereas the signal strength switch button is electrically connected to the signal emitting element.

7. The collar/headset microphone cable control device as claimed in claim 1, wherein the indicator lights include the power indicator light and the power charging indicator light whereas the power charging indicator light is electrically connected to the bus element.

8. The collar/headset microphone cable control device as claimed in claim 1, wherein the display element displays the signal state, sound volume scale, and mute state.
